(19) United States
(12) Patent Application Publication
(10) Pub. No.: US 2004/0140052 A1
(43) Pub. Date: Jul. 22, 2004

(54) Method for aligning key in semiconductor device

(76) Inventor: Il-seok Han, Kyunggi-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/747,768

(22) Filed: Dec. 29, 2003

(30) Foreign Application Priority Data
Dec. 28, 2002 (KR) 2002-86019

(51) Int. Cl. C23F 1/00; H01L 21/306

(52) U.S. Cl. 156/345.1

(57) ABSTRACT

The present invention discloses a method for aligning a key in a semiconductor device, which prevents misalignment in subsequent photo processes during a semiconductor key formation process. The method comprises the steps of: preparing a semiconductor substrate that is divided into a scribe lane region and a main chip region; depositing an oxide film on the semiconductor substrate for forming an align key; forming an area key and a first align key at the same time on the scribe lane region by selectively etching the oxide film by using a N-well ion implantation mask; performing a N-well ion implantation on the region which the oxide film is removed from; and forming a second align key in the area key, whose formation is already finished by removing the oxide film, by a silicon etching method using a P-well mask, upon a N-well process using a P-well ion implantation mask.

### BACKGROUND OF THE INVENTION

1. Field of the Invention

The present invention relates to a method for aligning a key in a semiconductor device, and more particularly, to a method for aligning a key in a semiconductor device which prevents misalignment in a subsequent photo process during a semiconductor key formation process.

2. Description of the Related Art

Generally, a semiconductor key formation process is carried out for preventing misalignment in a subsequent photo process.

A conventional key formation process is a method for preventing key misalignment upon conducting subsequent processes including a photo process for N-well ion implantation, a photo process for P-well ion implantation and a photo process for the local isolation of a device using a supplemental reticle and an additional process. This method is used after forming an alignment key on a scribe lane between main chips via silicon etching.

The above-mentioned scribe lane is referred to as the space of proper width formed so as to be cut without affecting any peripheral devices in the procedure of cutting a die in order to assemble a chip on a processed wafer.

The size of such a scribe lane ranges from 100 μm to 240 μm according to the area of a test pattern. However, as the die becomes smaller, the width of the scribe lane exerts a significant effect on a number of actual effective dies, and thus the scribe lane is mostly made to have an area of 100 μm or 120 μm.

Other than the test pattern, various forms of wafer align keys are inserted to the scribe lane for conducting the photo processes. In this scribe lane, various shapes of steppers exist including a laser step alignment mark, a field image align mark, a K-TV, a target for mounting a die, an overlay vernier, a distortion vernier, a rotation vernier and the like.

FIGS. 1a to 1f are sectional views illustrating a method for aligning a key in a semiconductor device according to the prior art.

Firstly, as shown in FIG. 1a, an oxide film 20 for preventing the damage of a silicon surface is deposited on a semiconductor substrate 10 upon conducting a subsequent ion implantation process. The semiconductor substrate 10 is divided into two portions, i.e., a scribe lane region 11 and a main chip region 12. When a wafer align key 60 is formed in the scribe lane region 11, a semiconductor device is formed in the main chip region 12.

As shown in FIG. 1b, a key photo process for key alignment is preformed on the oxide film 10 upon conducting a subsequent photo process. Then, a wafer alignment key 60 is formed on a silicon wafer 10 by performing a selective silicon etching process using a key reticle. At this time, since a photoresist 30 remains in the main chip region 12, a silicon etching is performed so that only the scribe lane region 11 has a step portion of about 500 to 1500 Å from the silicon surface.

As shown in FIG. 1c, by using the wafer align key 60 formed on the silicon wafer 10, a N-well photo process can be accurately conducted without misalignment. In a specific N-well open region of the main chip region 12, an ion implantation using a N-well photoresist 40 is performed.

As shown in FIG. 1d, after the ion implantation process, a photoresist removal process is performed.

As shown in FIG. 1e, after the N-well photo process, a P-well ion implantation process using a P-well photoresist 50 is performed. At this time, key alignment is performed using the align key 60 formed on the silicon wafer 10 as in FIG. 1b.

As shown in FIG. 1f, the P-well photoresist 50 for the P-well ion implantation process in FIG. 1e is removed to finish a N/P well process.

The subsequent photo process for local isolation of a device is also performed by using the aignent key 60 formed as in FIG. 1b.

The method for aligning a key in a semiconductor device according to the prior art described with reference to FIGS. 1a to 1f has a disadvantage that a key photo process and a selective etching process has to be performed, and the reticle has to be made for performing the key photo process.

### SUMMARY OF THE INVENTION

The present invention is designed in consideration of the problems of the prior art, and therefore it is an object of the present invention to provide a method for aligning a key in a semiconductor device which can prevent misalignment in a photo process during a conventional key formation process and, particularly, which can employ conventional N-well and P well reticles and conventional processes without any additional reticle manufacturing cost by omitting conventional key photo and etching processes.

It is another object of the present invention to provide a method for aligning a key in a semiconductor device which can form an area key and a first align key on a scribe lane region at the same time by selectively etching the oxide film that has been deposited on the entire surface of the wafer using a N-well ion implantation mask.

It is yet another object of the present invention to provide method for aligning a key in a semiconductor device which can perform a N-well ion implantation on the region which the oxide film is removed from in the same manner as a conventional semiconductor manufacture process.

It is yet still another object of the present invention to provide a method for aligning a key in a semiconductor device which can prevent misalignment in a subsequent photo process by forming a second align key within an area key, whose formation has already been finished by removing an oxide film using a silicon etching method of an oxide film/silicon dual etching using a P-well mask, upon a N-well process using a P-well ion implantation mask.

To achieve the above objects, there is provided a method for aligning a key in a semiconductor device according to the present invention, comprising the steps of: preparing a semiconductor substrate that is divided into a scribe lane region and a main chip region; depositing an oxide film on the semiconductor substrate for forming an align key; forming an area key and a first align key at the same time on the scribe lane region by selectively etching the oxide film by using a N-well ion implantation mask; performing a N-well ion implantation on the region which the oxide film is removed from; and forming a second align key in the area key, whose formation is already finished by removing the oxide film, by a silicon etching method using a P-well mask, upon a N-well process using a P-well ion implantation mask.

### BRIEF DESCRIPTION OF THE DRAWINGS

Other objects and aspects of the present invention will become apparent from the following description of embodiments with reference to the accompanying drawings in which:

FIGS. 1a to 1f are sectional views illustrating a method for aligning a key in a semiconductor device according to the prior art;

FIGS. 2a to 2g are sectional views illustrating a method for aligning a key in a semiconductor device by using an oxide film/silicon dual etching process according to a preferred embodiment of the present invention; and

FIGS. 3a to 3b are plane views illustrating the method for aligning a key in a semiconductor device by using an oxide film/silicon dual etching process according to the preferred embodiment of the present invention.

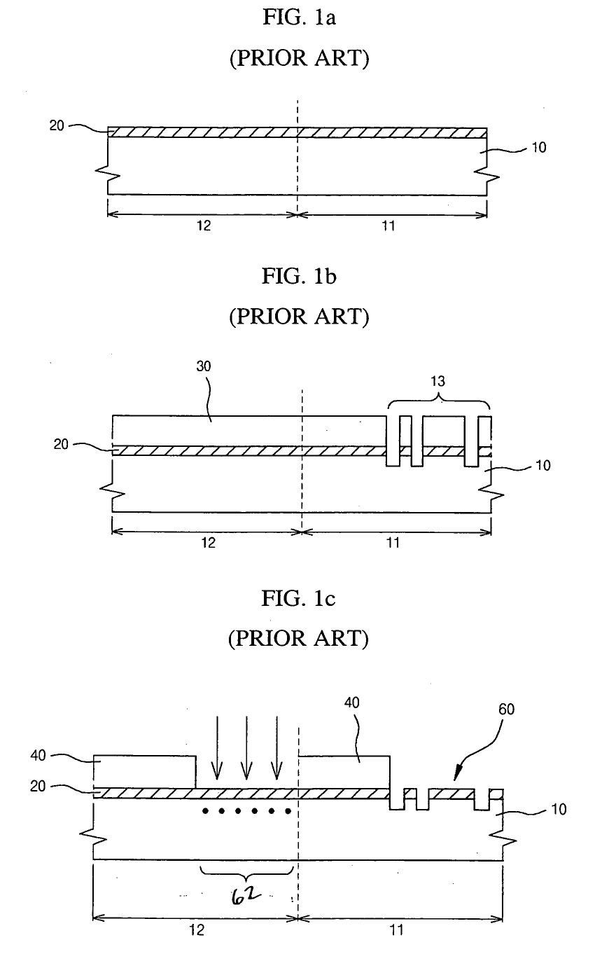

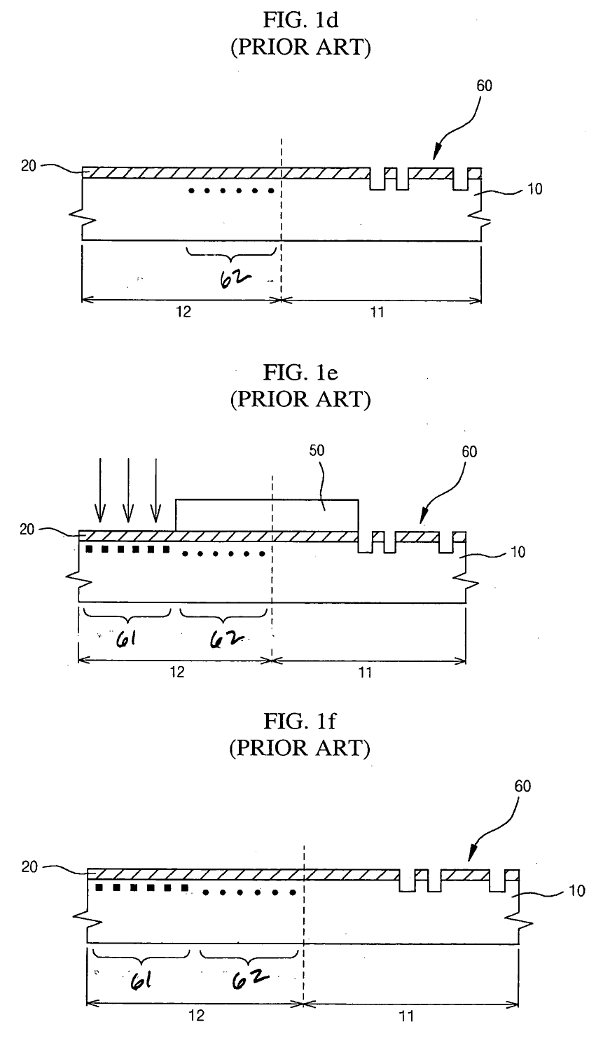

### DESCRIPTION OF THE PREFERRED EMBODIMENT

Hereinafter, a preferred embodiment of the present invention will be described in more detail referring to the drawings. In addition, the following embodiment is for illustration only, not intended to limit the scope of the invention.

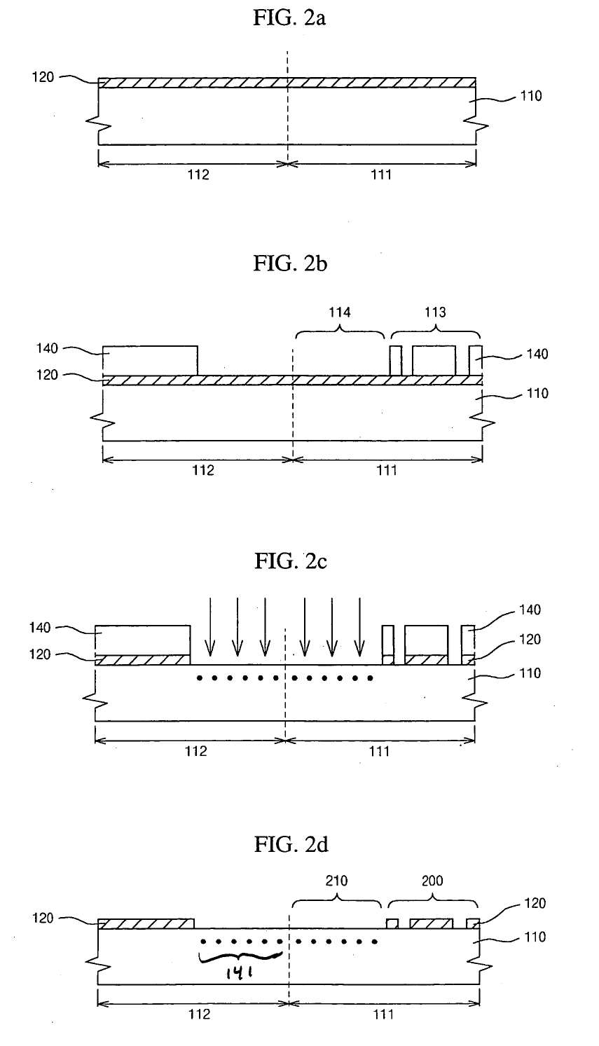

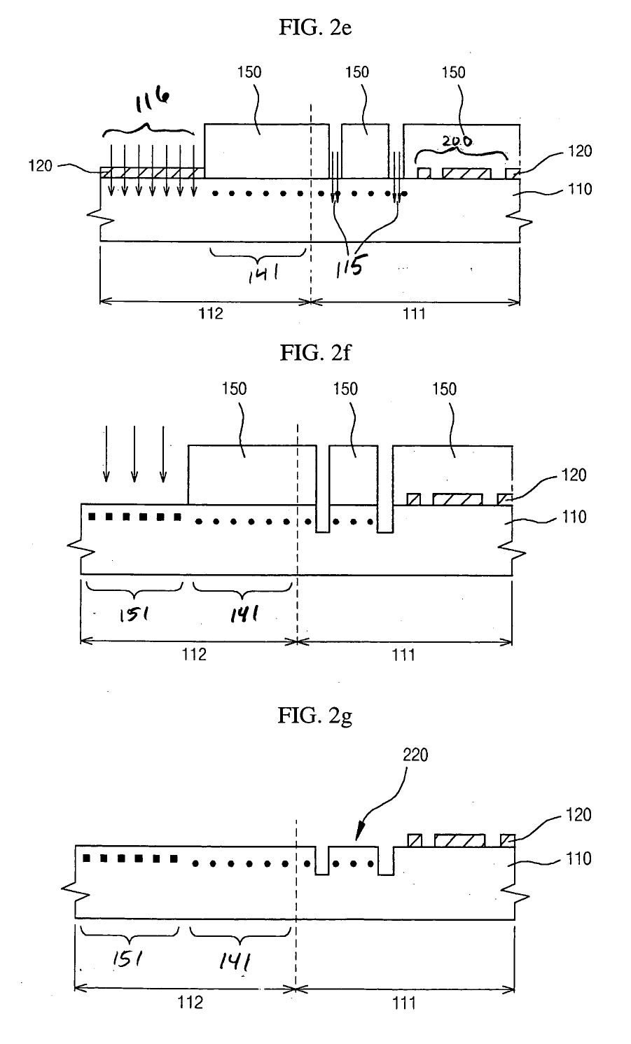

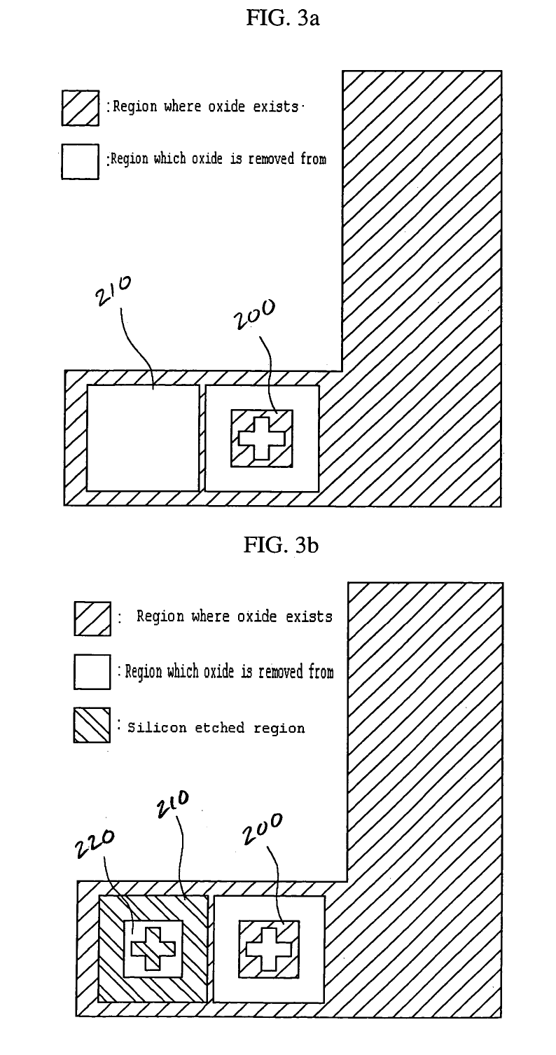

FIGS. 2a to 2g and FIGS. 3a to 3b are sectional views and plane views illustrating a method for aligning a key in a semiconductor device by using an oxide film/silicon dual etching process according to a preferred embodiment of the present invention.

First, as shown in FIG. 2a, an oxide film 120 is deposited on a semiconductor substrate 110 at a thickness of 800 to 1500 Å. At this time, the oxide film 120 is used as an etching preventive film during the silicon etching process, and, thus, in the preferred embodiment of the present invention, it is deposited at a thickness of 500 Å above the prior art.

As shown in FIG. 2b, in order to optionally perform a N-well ion implantation in a predetenrined region, a N-well photo process is carried out. At this time, conventionally, a N-well is exposed only to a specific portion of the main chip region 112, thus no subsequent key formation process for key alignment is performed on the scribe lane region 111. On the other hand, in the preferred embodiment of the present invention, by a method of etching the oxide film 120 using the N-well photo process, an align key is formed in the scribe lane region 111. Such a scribe region 111 is divided into a region 114 where a region key 210 widely and completely exposed is formed and a region 113 where a first align key 200 is formed.

Therefore, according to the preferred embodiment of the present invention, upon manufacturing a N-well reticle, if the two above-mentioned keys are inserted into the scribe lane as well as a conventional N-well ion implantation is performed in the N-well ion implantation region of the nain chip region 112. By this, the reticle manufacturing process can be carried out without any additional cost.

As shown in FIG. 2c, the oxide film 120 is removed from the area key forming region 114 by a selective etching process using a N-well ion implantation process, to form an area key 210 completely exposing the silicon surface. At the same time, a first align key 200 is formed in the frst align key forming region 113 due to a step portion of the oxide film by selective etching.

According to the preferred embodiment of the present invention, the area key 210 formed by N-well photo and selective etching methods have a size of 40 μm to 90 μm in a forward directional shape. On the other hand, the oxide film 120 of the second alignment key 220 forming region of the scribe lane 111 is removed.

Afterwards, a N-well ion implantation process is simultaneously performed on the main chip region 112 and the scribe lane region 111 with no oxide film 120. However, the key forming region of the scribe lane where the above-mentioned N-well ion implantation is performed is not a portion where a semiconductor device is to be formed, so it is not a matter for concern.

Next, as shown in FIG. 2d, the used N-well photoresist 140 is removed to finish the N-well formation process.

And, as shown in FIG. 2e, after the N-well photo process, a P-well photo process is conducted. At this time, wafer alignment for the photo process is performed by using a first align key 200 formed by a selective etching process using a N-well photo process. Afterwards, in the P-well photo process, a second alignment key 220 formation process for subsequent key alignment such as a LOCOS photo process, etc. is performed on the area key forming region 114 along with the P-well forming region of the main chip region 112.

Continually, as shown in FIG. 2g, the P-well forming region of the main chip region 112 is the region where the oxide film 120 remains, in which the oxide film 120 for a subsequent P-well ion implantation is selectively etched to expose the silicon wafer 110. At this time, a photoresist for forming an additional align key 220 exists in the area key forming region 114, and, upon selective etching for a P-well ion implantation, the surface of the silicon wafer is etched, in stead of etching the oxide film 120.

Therefore, it is possible to make a second align key 220 for conducting the subsequent photo process on the silicon surface without any additional process. Afterwards, a P-well is formed by ion implantation.

Then, as shown in FIG. 2g, a P-well photoresist 150 used in FIG. 2f is removed to thereby finishing the process. Afterwards, the subsequent photo process such as LOCOS, etc. may be conducted by using the second align key 220 formed in the area key forming region 114.

According to the preferred embodiment of the present invention, the shape of the second align key 220 formed on the scribe lane region 111 upon a P-well formation process is the same as the shape of the first align key 200, thereby enabling mask alignment using the second align key 220 upon the subsequent photo process such as LOCOS, etc.

FIGS. 3a to 3c are plane views of align keys formed by the method for aligning a key in a semiconductor device by using an oxide film/silicon dual etching process as shown in FIGS. 2a to 2g according to the preferred embodiment of the present invention.

By adapting the preferred embodiment of the present invention to every process requiring alignment in a semiconductor process, the object of the present invention can be achieved.

As seen from above, the present invention can prevent misalignment in a subsequent photo process during a conventional semiconductor key formation process, particularly, can employ an oxide film/silicon dual etching process using conventional N-well and P-well reticles and conventional processes without any additional reticle manufacturing costs by omitting conventional key photo and etching processes.

Furthermore, it is possible to form an area key and a first alignment key on a scribe lane region at the same time by selectively etching the oxide film that has been deposited on the entire surface of the wafer using a N-well ion implantation mask.

Furthermore, a N-well ion implantation can be performed on the region which the oxide film is removed from in the same manner as a conventional semiconductor manufacture process.

Moreover, misalignment can be prevented in a subsequent photo process by forming a second alignment key within an area key, whose formation is already finished by removing an oxide film, by using a silicon etching method of an oxide film/silicon dual etching using a P-well mask upon a N-well process using a P-well ion implantation mask.

Additionally, upon a subsequent photo process, an accurate alignment is enabled by using the second align key formed in the scribe lane even without a photo process using a key reticle.

What is claimed is:

1. A method for aligning a key in a semiconductor device, comprising the steps of:
preparing a semiconductor substrate that is divided into a scribe lane region and a main chip region;
depositing an oxide film on the semiconductor substrate for forming an align key;
forming an area key and a frst align key at the same time on the scribe lane region by selectively etching the oxide film by using a N-well ion implantation mask;
performing an N-well ion implantation on the region which the oxide film is removed from; and
forming a second align key in the area key, whose formation is already finished by removing the oxide film, by a silicon etching method using a P-well mask, upon a N-well process using a P-well ion implantation mask.

2. The method of claim 1, wherein the oxide film and the silicon are dual etched in the silicon etching step.

3. The method of claim 1, wherein the oxide film is deposited at a thickness of 800 to 1500 Å upon the N-well formation process.

4. The method of claim 1, wherein the method further comprises the step of removing the photoresist used as the N-well ion implantation mask before the N-well ion implantation step.

5. The method of claim 1, wherein the method further comprises the step of removing the photoresist used as the P-well ion implantation mask before the P-well ion implantation step.

6. The method of claim 1, wherein, upon performing an N-well selective etching process on the main chip region, the area key and the first align key using a step portion of the oxide film are formed at the same time by selectively etching the scribe lane region.

7. The method of claim 1, wherein the area key formed by N-well photo and selective etching processes has a size of 40 μm to 90 μm in a forward directional shape, and the oxide film on a second align key forming region of the scribe lane is removed.

8. The method of claim 1, wherein the semiconductor substrate is aligned using the first align key formed on the scribe lane upon the P-well photo process, and the second align key is formed in the area key where the oxide film is removed using the N-well photo process upon selective etching of the oxide film using a P-well ion implantation photo process.

9. The method of claim 1, wherein, upon the P-well photo process, the second align key to be formed on the scribe lane region is accurately aligned in the area key which the oxide film is removed by the alignment of the first align key.

10. The method of claim 9, wherein a silicon etching using the second align key as a pattern is performed using the oxide film removal process for the P-well ion implantation, simultaneously with the oxide film etching.

11. The method of claim 9, wherein the silicon of the second align key patterning portion is etched at a thickness of 800 to 1500 Å by performing a silicon etching for the formation of the second align key at an etching selection ratio of 0.8 to 1.2.

12. The method of claim 9, wherein the second align key formed on the scribe lane region upon the P-well process has the same shape as the first align key, thereby enabling a mask alignment using the second align key upon the subsequent photo process such as LOCOS, etc.
